(19) United States
(12) Patent Application Publication
(10) Pub. No.: US 2021/0063806 A1
(43) Pub. Date: Mar. 4, 2021

(54) DISPLAY DEVICE AND METHOD OF MANUFACTURING THE SAME

(71) Applicant: Samsung Display Co., Ltd., Yongin-si (KR)

(72) Inventors: Tae Hwan KIM, Yongin-si (KR); Hokyoon KWON, Seoul (KR); Jooil KIM, Cheonan-si (KR); Yunha NAM, Asan-si (KR); Soon Ryong PARK, Sejong-si (KR); Jaehyun CHAE, Hwaseong-si (KR)

(21) Appl. No.: 16/886,624

(22) Filed: May 28, 2020

(30) Foreign Application Priority Data
Aug. 28, 2019 (KR) 10-2019-0105768

(51) Int. Cl. G02F 1/1333; G02F 1/1335

(52) U.S. Cl. CPC G02F 1/133308; G02F 1/13338; G02F 2201/50; G02F 2202/28; G02F 1/133528

(57) ABSTRACT

A display device includes a display panel having a display region, a pad region, and a bendable region between the display region and the pad region; a protective member on the display region and the bendable region of the display panel; and an adhesive disposed in the bendable region in contact with a top surface of the display panel and a bottom surface of the protective member.

### CROSS REFERENCE TO RELATED APPLICATION

This application claims priority from and the benefit of Korean Patent Application No. 10-2019-0105768 filed on Aug. 28, 2019, which is hereby incorporated by reference for all purposes as if fully set forth herein.

### BACKGROUND

### Field

Exemplary implementations of the invention relate generally to a display device and a method of manufacturing the same and, more specifically, to display device having a bent region and a method of manufacturing the same.

### Discussion of the Background

Flat panel display devices are used as displays for replacing cathode ray tube display devices due to lightweight and thin characteristics thereof. As representative examples of such flat panel display devices, there are liquid crystal display devices and an organic light emitting diode display devices.

Recently, a flexible display device has been developed, which has a lower substrate and an upper substrate of a display panel, and may include a flexible material. A portion of the display panel may be bent and folded. For example, the lower substrate included in the display panel may be formed of a polyimide substrate, and the upper substrate included in the display panel may have a thin film encapsulation structure. In addition, the flexible display device may further include a bending protection layer disposed at a portion where the display panel is bent, and pad electrodes electrically connected to an external device. Connection electrodes formed to electrically connect pixels for emitting light may be disposed under the bending protection layer. In this case, the bending protection layer creates a neutral plane at a portion thereof to protect the connection electrodes. Furthermore, the flexible display device may further include a polarizing layer, a cover glass, and a touch screen electrode layer, which are disposed on a top surface of the display panel, and a lower protective film disposed on a bottom surface of the display panel.

### SUMMARY

Applicant discovered that the connection electrodes in such display devices are rarely damaged during the process of bending the bent portion, and most of the damage occurs by external impact after the bending process.

Display devices constructed according to the principles and exemplary implementations of the invention use an adhesive at a bent region to protect that region from impact. For example, an adhesive member may make contact with both the top surface of the display panel located in the bent region and a portion of the pad region, and the bottom surface of the protrusion of the cover window to protect the bent region from external impact.

In methods of manufacturing display devices according to the principles and exemplary implementations of the invention, an adhesive member is formed in the bent region of the display panel after the bent region of the display panel is bent, so that a cutting process to remove the bending protection layer may be omitted, and thus the manufacturing cost of the display device may be relatively reduced.

Additional features of the inventive concepts will be set forth in the description which follows, and in part will be apparent from the description, or may be learned by practice of the inventive concepts.

According to one aspect of the invention, a display device includes: a display panel having a display region, a pad region, and a bendable region between the display region and the pad region; a protective member on the display region and the bendable region of the display panel; and an adhesive disposed in the bendable region in contact with a top surface of the display panel and a bottom surface of the protective member.

The pad region may be at a bottom surface of the display panel when the bendable region is bent.

The display region may include a portion overlapping the pad region.

A polarizing structure may be disposed in the display region on the display panel, and a sensing structure may be disposed between the polarizing structure and the protective member.

The adhesive may include an adhesive member contacting a side surface of the polarizing structure and a side surface of the sensing structure, both of the side surfaces may be adjacent to the bendable region.

The protective member may include a cover window having a protrusion extending from an outer periphery of the display panel in the display region.

The adhesive may contact the side surfaces of the display panel and a bottom surface of the protrusion of the cover window.

A lower protective film may be disposed on a bottom surface of the display panel.

The lower protective film may expose the bottom surface of the display panel located in the bendable region.

The lower protective film may include: a first film disposed on the bottom surface of the display panel in the display region; and a second film disposed on the bottom surface of the display panel in the pad region and spaced apart from the first film on the bottom surface of the display panel.

The adhesive may be disposed in a space defined by the bottom surface of the display panel in the bendable region and side surfaces of the first and second films adjacent to the bendable region.

The adhesive may include an adhesive member extending from the bendable region to the pad region on the display panel.

A method of manufacturing a display device includes the steps of: providing a display panel having a display region, a pad region, and a bendable region located between the display region and the pad region; forming a polarizing structure in the display region on the display panel; providing a protective member; forming a sensing structure on a bottom surface of the protective member; forming the protective member with the sensing structure on the polarizing structure; bending the bendable region of the display panel; and forming an adhesive member in contact with a top surface of the display panel and the bottom surface of the protective member in the bendable region.

Forming a lower protective film in the display region and the pad region may be on a bottom surface of the display panel.

The lower protective film may expose the bottom surface of the display panel located in the bendable region.

The step of forming the lower protective film in the display region and the pad region on the bottom surface of the display panel may include: forming a first film on the bottom surface of the display panel in the display region; and forming a second film on the bottom surface of the display panel in the pad region spaced apart from the first film on the bottom surface of the display panel.

The adhesive member may be formed in a space defined by the bottom surface of the display panel in the bendable region and side surfaces of the first and second films adjacent to the bendable region.

The pad region may be disposed at a bottom surface of the display panel when the bendable region is bent, and a portion of the display region may overlap the pad region.

The adhesive member may extend from the bendable region to the pad region on the display panel.

The adhesive member may contact a side surface of the polarizing structure and a side surface of the sensing structure both of the side surfaces may be adjacent to the bendable region.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the inventive concepts.

FIG. 1 is a plan view of an exemplary embodiment of a display device constructed according to principles of the invention.

FIG. 2 is a perspective view showing the bent shape of the display panel of FIG. 1.

FIG. 3 is a block diagram of an exemplary embodiment of an external device electrically connected to the display device of FIG. 1.

FIG. 4 is a cross-sectional view taken along the line I-I′ of FIG. 1.

FIG. 5 is an enlarged cross-sectional view showing region ‘A’ of the display device of FIG. 4.

FIG. 6 is a cross-sectional view of another exemplary embodiment taken along the line I-I′ of FIG. 1.

FIG. 7 is a plan view of another exemplary embodiment of a display device constructed according to principles of the invention.

FIG. 8 is a cross-sectional view taken along line II-IF of FIG. 7.

FIG. 9 is a cross-sectional view taken along line of FIG. 7.

FIGS. 10, 11, 12, and 13 are cross-sectional views of an exemplary method of manufacturing a display device according to principles of the invention.

### DETAILED DESCRIPTION

In the following description, for the purposes of explanation, numerous specific details are set forth in order to provide a thorough understanding of various exemplary embodiments or implementations of the invention. As used herein “embodiments” and “implementations” are interchangeable words that are non-limiting examples of devices or methods employing one or more of the inventive concepts disclosed herein. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

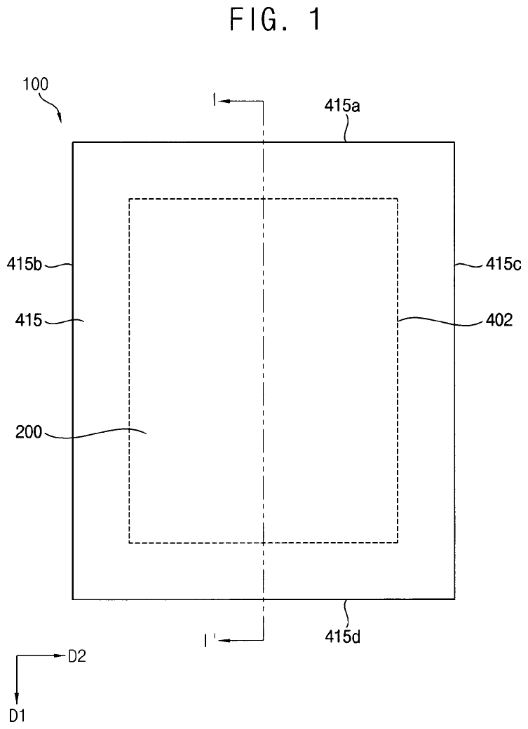

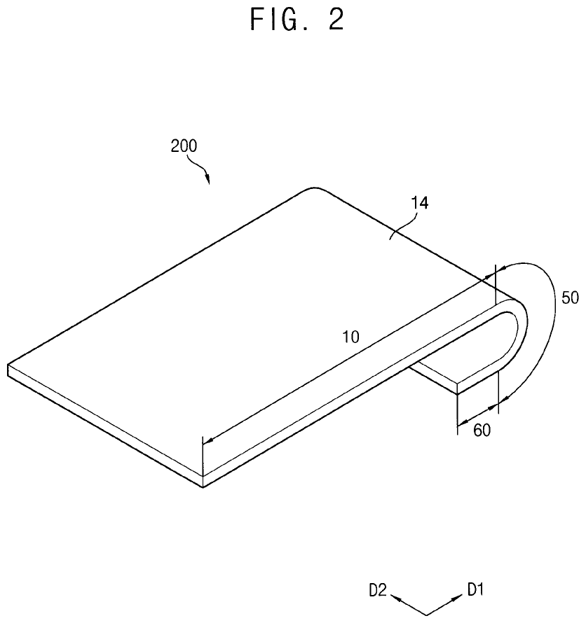

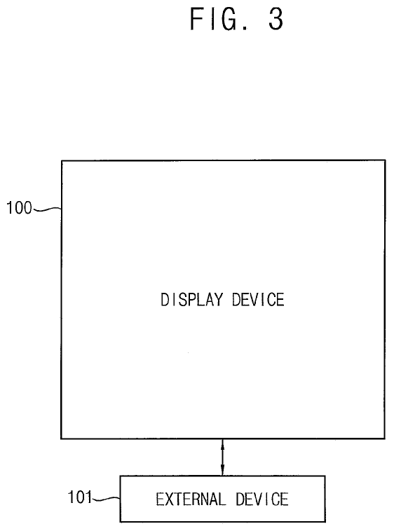

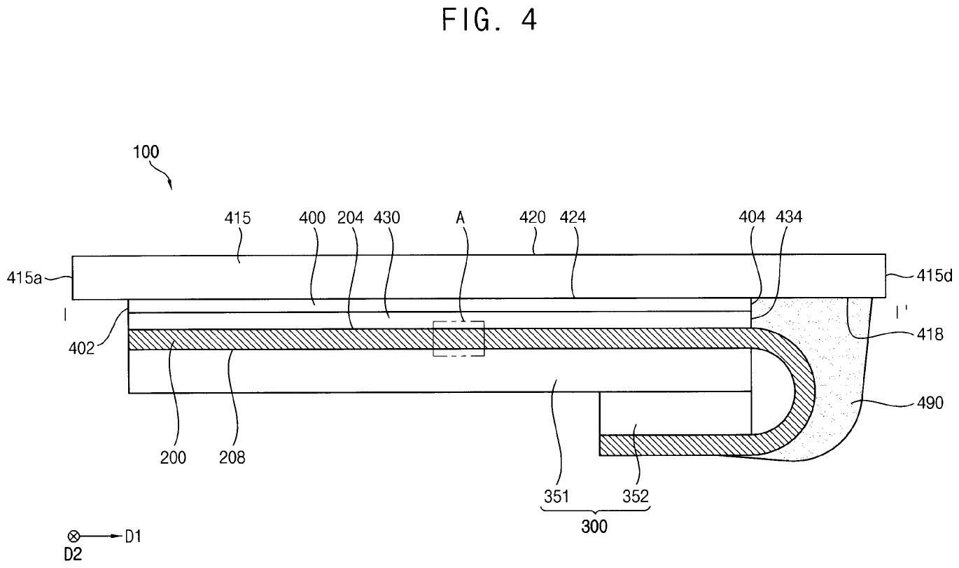

FIG. 1 is a plan view of an exemplary embodiment of a display device constructed according to principles of the invention. FIG. 2 is a perspective view showing the bent shape of the display panel of FIG. 1. FIG. 3 is a block diagram of an exemplary embodiment of an external device electrically connected to the display device of FIG. 1. FIG. 4 is a cross-sectional view taken along the line I-I′ of FIG. 1.

Referring to FIGS. 1, 2, 3 and 4, the display device 100 may include a display panel 200, a polarizing structure 430, a sensing structure 400, a lower protective film 300, an adhesive, which may take the form of an adhesive member 490, a protective member, which may take the form of a cover window 415, and the like. In this case, the lower protective film 300 may include a first film 351 and a second film 352.

As shown in FIG. 2, the display panel 200 may have a display region 10, a bendable region 50, which may be bent during manufacture into a bent position such as that shown in FIG. 2, and a pad region 60. The display panel 200 may have a top surface 204 and a bottom surface 208. The pad region 60 may be spaced apart from the display region 10, and the bendable region 50 may be located between the display region 10 and the pad region 60. For example, pixels may be disposed in the display region 10, and an image may be displayed through the pixels. Pad electrodes electrically connected to an external device 101 may be disposed in the pad region 60, and connection electrodes formed to electrically connect the pad electrode to the pixels may be disposed in the bendable region 50. In the exemplary embodiments, when the bendable region 50 is bent, the pad region 60 may be opposed to or located on a bottom surface 208 of the display panel 200, and a portion 14 of the display region 10 may overlap the pad region 60.

Although each of the display region 10, the bendable region 50, and the pad region 60 has been described as having a generally rectangular shape when viewed in a plan view, the shape of each of the display region 10, the bendable region 50, and the pad region 60 is not limited thereto. For example, each of the display region 10, the bendable region 50, and the pad region 60 may have a generally triangular shape, a generally rhombical shape, a generally polygonal shape, a generally circular shape, a generally toroidal shape, or a generally elliptical shape when viewed in a plan view.

As shown in FIG. 3, the external device 101 may be electrically connected to the display device 100 (e.g., the pad electrodes of the display panel 200) through a flexible printed circuit board. The external device 101 may provide a data signal, a scan signal, a light emission signal, an initialization signal, a power supply voltage, a sensing signal, and the like to the display device 100. In addition, a driving integrated circuit may be mounted on the flexible printed circuit board. In other exemplary embodiments, the driving integrated circuit may be mounted in the pad region 60 of the display panel 200 so as to be adjacent to the pad electrodes.

Referring again to FIG. 4, the polarizing structure 430 may be disposed in the display region 10 on the display panel 200. In the exemplary embodiments, the polarizing structure 430 may be disposed only in the display region 10 without extending into the bendable region 50 before it is bent. The polarizing structure 430 may block external light incident to the display panel 200 from an outside. For example, the polarizing structure 430 may include a linear polarizing film and a λ/4 phase retardation film. The λ/4 phase retardation film may be disposed on the display panel 200. The λ/4 phase retardation film may convert a phase of light. For example, the λ/4 phase retardation film may convert vertically oscillating light or horizontally oscillating light into right circular polarization light or left circular polarization light, may convert the right circular polarization light or the left circular polarization light into the vertically oscillating light or the horizontally oscillating light. The λ/4 phase retardation film may include at least one of a birefringent film including a polymer, an alignment film formed of a liquid crystal polymer, a film including an alignment layer formed of a liquid crystal polymer, and the like.

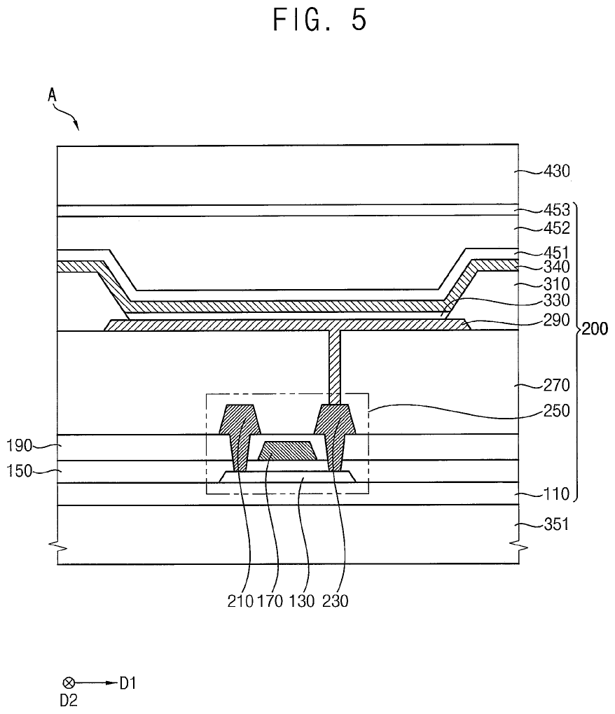

The linear polarizing film may be disposed on the λ/4 phase retardation film. The linear polarizing film may selectively transmit light. For example, the linear polarizing film may transmit the vertically oscillating light or the horizontally oscillating light. In this case, the linear polarizing film may have a horizontal line pattern or a vertical line pattern. When the linear polarizing film includes the horizontal line pattern, the linear polarizing film may block the vertically oscillating light, and may transmit the horizontally oscillating light. When the linear polarizing film has the vertical line pattern, the linear polarizing film may block the horizontally oscillating light, and may transmit the vertically oscillating light. The light transmitted through the linear polarizing film may pass through the λ/4 phase retardation film. As described above, the λ/4 phase retardation film may convert the phase of light. For example, when the vertically and horizontally oscillating lights pass through the linear polarizing film, the linear polarizing film having the horizontal line pattern may transmit the horizontally oscillating light. When the horizontally oscillating light passes through the λ/4 phase retardation film, the horizontally oscillating light may be converted into the left circular polarization light. The left circular polarization light may be reflected by an upper electrode 340 of FIG. 5, and the light may be converted into the right circular polarization light. When the right circular polarization light passes through the λ/4 phase retardation film, the light may be converted into the vertically oscillating light. In this case, the vertically oscillating light may not be transmitted through the linear polarizing film having the horizontal line pattern. Accordingly, the light may be extinguished by the linear polarizing film and the λ/4 phase retardation film. For example, the linear polarizing film may include an iodine-based material, a dye-containing material, a polyene-based material, and the like.

The sensing structure 400 may be disposed on the polarizing structure 430. In other words, the sensing structure 400 may be located between the polarizing structure 430 and the cover window 415. In the exemplary embodiments, the sensing structure 400 may be disposed only in the display region 10 without being disposed in the bendable region 50. The sensing structure 400 may be substantially transparent, and the image may be recognized by a user of the display device 100 through the sensing structure 400. The sensing structure 400 may include sensing electrodes. The sensing structure 400 may detect a portion of a body of the user, an object, or the like located in front of the display device 100 through the sensing electrode. In other words, the sensing signal generated from the external device 101 may be transmitted to the sensing electrode through the pad electrodes. The external device 101 may detect the portion of the body of the user, the object, or the like located in front of the display device 100 by receiving the sensing signal transmitted to the sensing electrode. In the exemplary embodiments, the sensing electrode may include a proximity sensor electrode formed to detect proximity to the user or the object located in front of the display device 100, or a touch sensor electrode formed to detect a touch of the portion of the body of the user. In some embodiments, the sensing structure 400 may further include a connection wire formed to electrically connect the sensing electrode to the pad electrodes. The sensing electrodes and the connection wires may include at least one of carbon nanotubes (CNT), transparent conductive oxide (TCO), indium tin oxide (ITO), indium gallium zinc oxide (IGZO), zinc oxide (ZnO), graphene, Ag nanowires (AgNW), copper (Cu), chromium (Cr), and the like.

Although the sensing structure 400 has been described as being disposed on the polarizing structure 430, the configuration of the exemplary embodiments are not limited thereto. For example, the sensing structure 400 may be disposed on the display panel 200, and the polarizing structure 430 may be disposed on the sensing structure 400.

Referring again to FIGS. 1 and 4, the cover window 415 may be disposed on the sensing structure 400. The cover window 415 may be located over the display region 10 and the bendable region 50 of the display panel 200. The cover window 415 may have a top surface 420 and a bottom surface 424. In addition, the cover window 415 may further include first, second, third, and fourth protrusions 415a, 415b, 415c, and 415d integrally formed with the main body of the cover window 415 and extending outwardly from an outer periphery 402 of the display panel 200 located in the display region 10. In other words, the cover window 415 may overlap the display panel 200 located in the display region 10 and the bendable region 50, and the area of the cover window 415 may be larger than the area of the display region 10 of the display panel 200. The cover window 415 may protect the polarizing structure 430, the sensing structure 400, and the display panel 200. The cover window 415 may include tempered glass, tempered plastic, and the like.

The lower protective film 300 may be disposed on the bottom surface 208 of the display panel 200 to protect the display panel 200. In the exemplary embodiments, the lower protective film 300 may expose the bottom surface 208 of the display panel 200 located in the bendable region 50. For example, the first film 351 may be disposed on the bottom surface 208 of the display panel 200 located in the display region 10, and the second film 352 may be disposed on the bottom surface 208 of the display panel 200 located in the pad region 60 while being spaced apart from the first film 351 on the bottom surface 208 of the display panel 200. When the display panel 200 is bent, the second film 352 may be located on a bottom surface of the first film 351. The lower protective film 300 may include at least one of polyethylene terephthalate (PET), polyethylene naphthalene (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polyphenylene oxide (MPPO), and the like. In other exemplary embodiments, a double-sided adhesive film may be disposed between the bottom surface of the first film 351 and a bottom surface of the second film 352 to adhere the first film 351 to the second film 352.

The adhesive member 490 may be disposed between the bendable region 50 of the display panel 200 and the fourth protrusion 415d of the cover window 415. In the exemplary embodiments, the adhesive member 490 may simultaneously make direct contact with a top surface 204 of the display panel 200 located in the bendable region 50 and a bottom surface 418 of the fourth protrusion 415d of the cover window 415. In addition, the adhesive member 490 may make direct contact with a side surface 434 of the polarizing structure 430 and a side surface 404 of the sensing structure 400 which are adjacent to the bendable region 50 (or adjacent to the fourth protrusion 415d). Furthermore, the adhesive member 490 may extend from the bendable region 50 to and across the entire pad region 60 on the display panel 200. The adhesive member 490 may include at least one of an adhesive, a photocurable resin, a thermosetting resin, and the like. For example, the adhesive member 490 may include at least one of an epoxy resin, an amino resin, a phenol resin, a urea resin, a melamine resin, an unsaturated polyester resin, a polyurethane resin, a polyimide resin, and the like.

In the display device 100 according to the exemplary embodiments of the invention, the adhesive member 490 simultaneously makes contact with both 1) the top surface 204 of the display panel 200, which is located in the bendable region 50 and a portion of the pad region 60, and 2) the bottom surface 418 of the fourth protrusion 415d of the cover window 415, so that the bendable region 50 of the display panel 200 (or the connection electrodes disposed in the bendable region 50) may be protected from an external impact.

For example, a conventional display device may include a bending protection layer disposed in the bending region of the display panel. The bending protection layer may be formed in the bending region on the display panel before the bending region is bent. The bending protective layer is disposed in the bending region, so that a neutral plane may be located at a portion where the connection electrodes are disposed (or located higher than the portion where the connection electrodes are disposed) in the bending region. Therefore, while the bending region is bent, the connection electrodes may not be broken. In addition, after the bending region is bent, the bending protection layer may protect the connection electrodes disposed in the bending region from an external impact. In a conventional process of manufacturing a display device, after the bending protection layer is formed to have an area relatively wider than an area of the bending region on the display panel, a process of cutting the bending protection layer such that the area of the bending protection layer is equal to the area of the bending region may be performed. For example, after the bending protection layer is formed to have an area wider than the area of the bending region, a cutting process of removing unnecessary portions of the bending protection layer such that the bending protection layer has a uniform thickness in the bending region has to be added in the manufacturing process. In other words, the manufacturing cost of the conventional display device is increased due to the required cutting process.

The display device 100 according to the exemplary embodiments of the invention may include the adhesive member 490 formed in the bendable region 50 of the display panel 200 after the bendable region 50 of the display panel 200 is bent. For example, experimentally, as a result of analyzing the cause of damage to the connection electrodes, it has been found that the connection electrodes are rarely damaged during a bending process, and most of the damage occurs by an external impact after the bending process. Accordingly, the cutting process in methods according to exemplary embodiments can be omitted, so that the manufacturing cost of the display device 100 may be relatively reduced.

FIG. 5 is an enlarged cross-sectional view showing region ‘A’ of the display device of FIG. 4. The display panel 200 may include a substrate 110, a semiconductor element 250, a planarization layer 270, a lower electrode 290, a pixel defining layer 310, a light emitting layer 330, an upper electrode 340, a first thin film encapsulation layer 451, a second thin film encapsulation layer 452, a third thin film encapsulation layer 453, and the like. The semiconductor element 250 may include an active layer 130, a gate insulating layer 150, a gate electrode 170, an insulating interlayer 190, a source electrode 210, and a drain electrode 230.

The substrate 110 including a transparent or opaque material may be provided. The substrate 110 may be disposed on the fourth adhesive member 205. The substrate 110 may be formed of a transparent resin substrate. Examples of the transparent resin substrate that may be used as the substrate 110 include a polyimide substrate. In this case, the polyimide substrate may include a first polyimide layer, a barrier film layer, a second polyimide layer, and the like. In other exemplary embodiments, the substrate 110 may include at least one of a quartz substrate, a synthetic quartz substrate, a calcium fluoride substrate, a fluorine-doped quartz substrate (F-doped quartz substrate), a soda lime glass substrate, a non-alkali glass substrate, etc.

A buffer layer may be disposed on the substrate 110. The buffer layer may prevent metal atoms or impurities from diffusing from the substrate 110 to the semiconductor element 250, and may control a heat transfer rate during a crystallization process for forming the active layer to obtain a substantially uniform active layer. In addition, when a surface of the substrate 110 is not uniform, the buffer layer may serve to improve flatness of the surface of the substrate 110. Depending on the type of substrate 110, at least two buffer layers may be provided on the substrate 110, or the buffer layer may not be provided. For example, the buffer layer may include an organic material or an inorganic material.

The active layer 130 may be disposed on the substrate 110. The active layer 130 may include at least one of a metal oxide semiconductor, an inorganic semiconductor (e.g., amorphous silicon or poly silicon semiconductor), an organic semiconductor, etc. The active layer 130 may have source and drain regions.

The gate insulating layer 150 may be disposed on the active layer 130. For example, the gate insulating layer 150 may sufficiently cover the active layer 130 on the substrate 110, and may have a substantially flat top surface without creating a step around the active layer 130. In some exemplary embodiments, the gate insulating layer 150 may be disposed along a profile of the active layer 130 with a uniform thickness to cover the active layer 130 on the substrate 110. The gate insulating layer 150 may include at least one of a silicon compound, a metal oxide, etc. For example, the gate insulating layer 150 may include at least one of a silicon oxide (SiOₓ), a silicon nitride (SiNₓ), a silicon oxynitride (SiOₓN_{y}), a silicon oxycarbide (SiOₓC_{y}), a silicon carbonitride (SiCₓN_{y}), an aluminum oxide (AlOₓ), an aluminum nitride (AlNₓ), a tantalum oxide (TaOₓ), a hafnium oxide (HfOₓ), a zirconium oxide (ZrOₓ), a titanium oxide (TiOₓ), etc. In other exemplary embodiments, the gate insulating layer 150 may have a multilayer structure including a plurality of insulating layers. For example, the insulating layers may have mutually different thicknesses or may include mutually different materials.

The gate electrode 170 may be disposed on the gate insulating layer 150. The gate electrode 170 may be disposed at a portion of the gate insulating layer 150 under which the active layer 130 is located. The gate electrode 170 may include at least one of a metal, an alloy, metal nitride, conductive metal oxide, a transparent conductive material, etc. For example, the gate electrode 170 may include at least one of gold (Au), silver (Ag), aluminum (Al), tungsten (W), copper (Cu), platinum (Pt), nickel (Ni), titanium (Ti), palladium (Pd), magnesium (Mg), calcium (Ca), lithium (Li), chromium (Cr), tantalum (Ta), molybdenum (Mo), scandium (Sc), neodymium (Nd), iridium (Ir), an aluminum-containing alloy, aluminum nitride (AlNₓ), a silver-containing alloy, tungsten nitride (WNₓ), a copper-containing alloy, a molybdenum-containing alloy, titanium nitride (TiNₓ), chromium nitride (CrNₓ), tantalum nitride (TaNₓ), strontium ruthenium oxide (SrRuₓO_{y}), zinc oxide (ZnOₓ), indium tin oxide (ITO), tin oxide (SnOₓ), indium oxide (InOₓ), gallium oxide (GaOₓ), indium zinc oxide (IZO), etc. These may be used alone or in combination with each other. In other exemplary embodiments, the gate electrode 170 may have a multilayer structure including a plurality of metal layers. For example, the metal layers may have mutually different thicknesses or may include mutually different materials.

The insulating interlayer 190 may be disposed on the gate electrode 170. The insulating interlayer 190 may sufficiently cover the gate electrode 170 on the gate insulating layer 150, and may have a substantially flat top surface without creating a step around the gate electrode 170. In some exemplary embodiments, the insulating interlayer 190 may be disposed along a profile of the gate electrode 170 with a uniform thickness to cover the gate electrode 170 on the gate insulating layer 150. The insulating interlayer 190 may include a silicon compound, metal oxide, etc. In some embodiments, the insulating interlayer 190 may have a multilayer structure including a plurality of insulating layers. For example, the insulating layers may have mutually different thicknesses or may include mutually different materials.

The source electrode 210 and the drain electrode 230 may be disposed on the insulating interlayer 190. The source electrode 210 may be connected to the source region of the active layer 130 through a contact hole formed by removing first parts of the gate insulating layer 150 and the insulating interlayer 190, and the drain electrode 230 may be connected to the drain region of the active layer 130 through a contact hole formed by removing second parts of the gate insulating layer 150 and the insulating interlayer 190. Each of the source electrode 210 and the drain electrode 230 may include at least one of a metal, an alloy, a metal nitride, a conductive metal oxide, a transparent conductive material, etc. These may be used alone or in combination with each other. In other exemplary embodiments, each of the source electrode 210 and the drain electrode 230 may have a multilayer structure including a plurality of metal layers. For example, the metal layers may have mutually different thicknesses or may include mutually different materials.

Accordingly, the semiconductor element 250 including the active layer 130, the gate insulating layer 150, the gate electrode 170, the insulating interlayer 190, the source electrode 210, and the drain electrode 230 may be provided.

Although the semiconductor element 250 has been described as having a top gate structure, the exemplary embodiments are not limited thereto. For example, the semiconductor element 250 may have a bottom gate structure, a double gate structure, etc.

In addition, although the display device 100 has been described as including one semiconductor element, the exemplary embodiments are not limited thereto. For example, the display device 100 may include at least one semiconductor element and at least one storage capacitor.

The planarization layer 270 may be disposed on the insulating interlayer 190, the source electrode 210, and the drain electrode 230. For example, the planarization layer 270 may be relatively thick. In this case, the planarization layer 270 may have a substantially flat top surface. In order to implement such a flat top surface of the planarization layer 270, a planarization process may be additionally performed on the planarization layer 270. In some exemplary embodiments, the planarization layer 270 may be disposed along a profile of the source electrode 210 and the drain electrode 230 with a uniform thickness on the insulating interlayer 190. The planarization layer 270 may be formed of an organic material or an inorganic material. In the exemplary embodiments, the planarization layer 270 may include an organic material. For example, the planarization layer 270 may include at least one of a photoresist, a polyacryl-based resin, a polyimide-based resin, a polyamide-based resin, a siloxane-based resin, an acryl-based resin, an epoxy-based resin, etc.

The lower electrode 290 may be disposed on the planarization layer 270. The lower electrode 290 may be connected to the drain electrode 230 through a contact hole formed by removing a portion of the planarization layer 270, and the lower electrode 290 may be electrically connected to the semiconductor element 250. The lower electrode 290 may include at least one of a metal, an alloy, a metal nitride, a conductive metal oxide, a transparent conductive material, etc. These may be used alone or in combination with each other. In other exemplary embodiments, the lower electrode 290 may have a multilayer structure including a plurality of metal layers. For example, the metal layers may have mutually different thicknesses or may include mutually different materials.

The pixel defining layer 310 may be disposed on the planarization layer 270. For example, the pixel defining layer 310 may expose a portion of a top surface of the lower electrode 290 while covering both sides of the lower electrode 290. The pixel defining layer 310 may be formed of an organic material or an inorganic material. In the exemplary embodiments, the pixel defining layer 310 may include an organic material.

The light emitting layer 330 may be disposed on the pixel defining layer 310 and the lower electrode 290. The light emitting layer 330 may be formed by using at least one of light emitting materials for emitting different color lights (i.e., red light, green light, blue light, etc.) according to sub-pixels. Alternatively, the light emitting layer 330 may be formed by laminating a plurality of light emitting materials for emitting different color lights such as red light, green light, and blue light to emit white light as a whole. In this case, a color filter may be disposed on the light emitting layer 330 that is disposed on the lower electrode 290. The color filter may include at least one of a red color filter, a green color filter, and a blue color filter. In some embodiments, the color filter may include a yellow color filter, a cyan color filter, and a magenta color filter. The color filter may include a photosensitive resin or a color photoresist.

The upper electrode 340 may be disposed on the light emitting layer 330 and the pixel defining layer 310. The upper electrode 340 may include at least one of a metal, an alloy, a metal nitride, a conductive metal oxide, a transparent conductive material, etc. These may be used alone or in combination with each other. In other exemplary embodiments, the upper electrode 340 may have a multilayer structure including a plurality of metal layers. For example, the metal layers may have mutually different thicknesses or may include mutually different materials.

The first thin film encapsulation layer 451 may be disposed on the upper electrode 340. The first thin film encapsulation layer 451 may be disposed along a profile of the upper electrode 340 with a uniform thickness to cover the upper electrode 340. The first thin film encapsulation layer 451 may prevent the light emitting layer 330 from being deteriorated due to penetration of moisture, oxygen, or the like. In addition, the first thin film encapsulation layer 451 may function to protect the display panel 200 from an external impact. The first thin film encapsulation layer 451 may include inorganic materials having flexibility.

The second thin film encapsulation layer 452 may be disposed on the first thin film encapsulation layer 451. The second thin film encapsulation layer 452 may improve flatness of the display panel 200 and protect the display panel 200. The second thin film encapsulation layer 452 may include organic materials having flexibility.

The third thin film encapsulation layer 453 may be disposed on the second thin film encapsulation layer 452. The third thin film encapsulation layer 453 may be disposed along a profile of the second thin film encapsulation layer 452 with a uniform thickness to cover the second thin film encapsulation layer 452. The third thin film encapsulation layer 453 may prevent the light emitting layer 330 from being deteriorated due to the penetration of moisture, oxygen, or the like together with the first thin film encapsulation layer 451. In addition, the third thin film encapsulation layer 453 may function to protect the display panel 200 from an external impact together with the first thin film encapsulation layer 451 and the second thin film encapsulation layer 452. The third thin film encapsulation layer 453 may include inorganic materials having flexibility.

Accordingly, the display panel 200 may include the substrate 110, the semiconductor element 250, the planarization layer 270, the lower electrode 290, the pixel defining layer 310, the light emitting layer 330, the upper electrode 340, the first thin film encapsulation layer 451, the second thin film encapsulation layer 452, and the third thin film encapsulation layer 453.

Although the display device 100 of exemplary implementations of the invention has been described as being an organic light emitting diode display device, the exemplary embodiments are not limited thereto. In other exemplary embodiments, the display device 100 may include a liquid crystal display device (LCD), a field emission display device (FED), a plasma display device (PDP), an electrophoretic image display device (EPD), or other known type of display device.

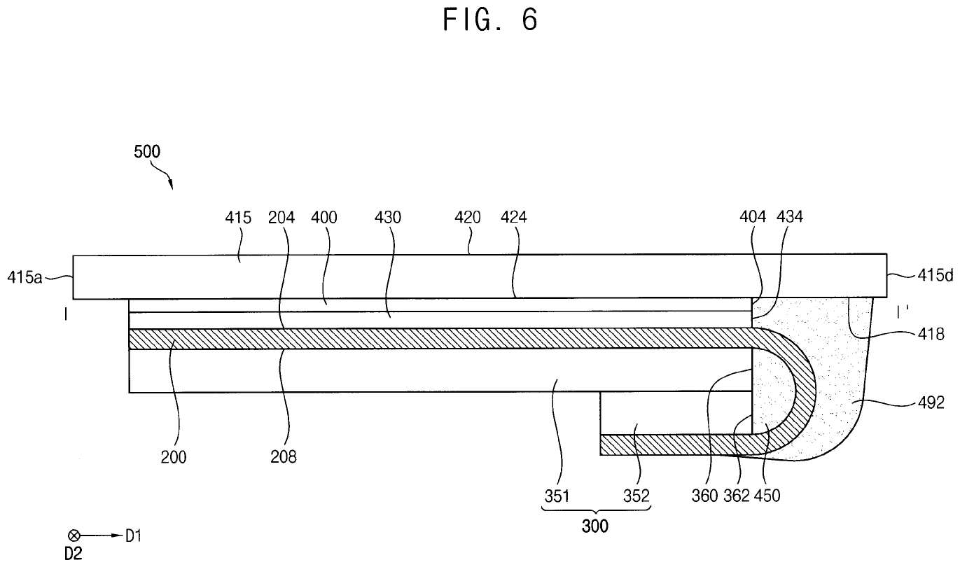

FIG. 6 is a cross-sectional view of another exemplary embodiment taken along the line I-I′ of FIG. 1. The display device 500 illustrated in FIG. 6 may have a configuration substantially identical or similar to the configuration of the display device 100 described with reference to FIGS. 1 to 5 except for an adhesive member 492. In FIG. 6, redundant descriptions of components substantially identical or similar to the components described with reference to FIGS. 1 to 5 will be omitted to avoid redundancy.

Referring to FIG. 6, the display device 500 may include a display panel 200, a polarizing structure 430, a sensing structure 400, a lower protective film 300, an adhesive member 492, a cover window 415, and the like. In this case, the lower protective film 300 may include a first film 351 and a second film 352.

The adhesive member 492 may be disposed between the bendable region 50 of the display panel 200 and the fourth protrusion 415d of the cover window 415. In the exemplary embodiments, the adhesive member 492 may be disposed in a space 450 defined by the bottom surface 208 of the display panel 200 located in the bendable region 50 and side surfaces 360 and 362 of the first and second films 351 and 352 adjacent to the bendable region 50. For example, this space may correspond to a space 450 in which the first film 351 and the second film 352 are spaced apart from each other before the bendable region 50 of the display panel 200 is bent.

In addition, the adhesive member 492 may simultaneously make direct contact with the top surface 204 of the display panel 200 located in the bendable region 50 and 2) the bottom surface 418 of the fourth protrusion 415d of the cover window 415, and may make direct contact with the side surface 434 of the polarizing structure 430 and the side surface 404 of the sensing structure 400 which are adjacent to the bendable region 50 (or adjacent to the fourth protrusion 415d). Furthermore, the adhesive member 492 may extend from the bendable region 50 to the pad region 60 on the display panel 200.

The adhesive member 492 may include at least one of an adhesive, a photocurable resin, a thermosetting resin, and the like. For example, the adhesive member 492 may include at least one of an epoxy resin, an amino resin, a phenol resin, a urea resin, a melamine resin, an unsaturated polyester resin, a polyurethane resin, a polyimide resin, and the like.

The display device 500 according to the exemplary embodiments of the invention includes the adhesive member 492 additionally disposed in the space 450 defined by the bottom surface 208 of the display panel 200 located in the bendable region 50 and the side surfaces 360 and 362 of the first and second films 351 and 352 adjacent to the bendable region 50, so that the bendable region 50 of the display panel 200 (or the connection electrodes disposed in the bendable region 50) may be protected from an external impact.

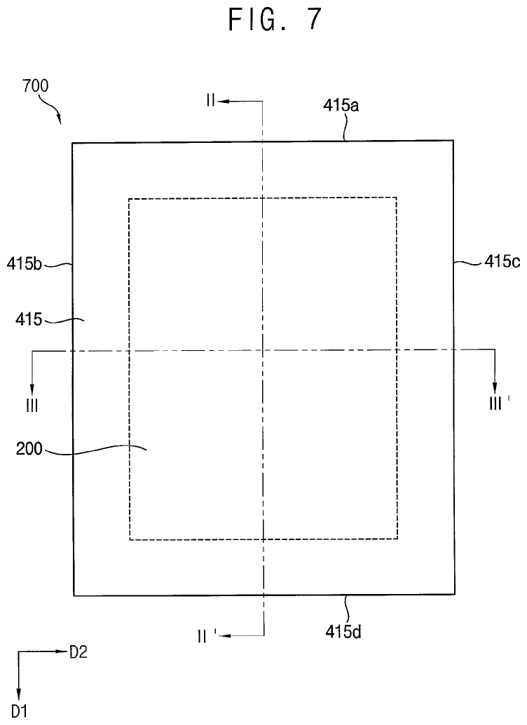

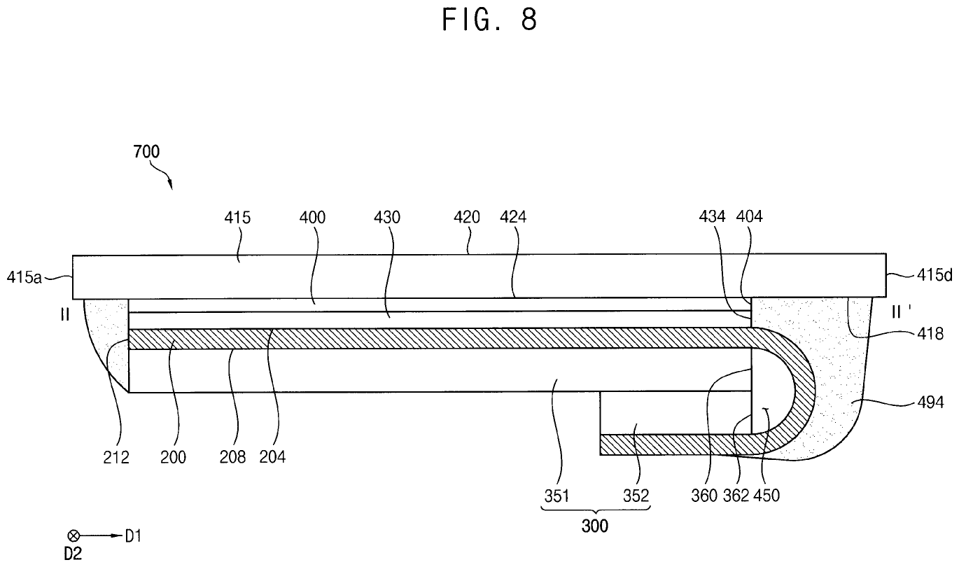

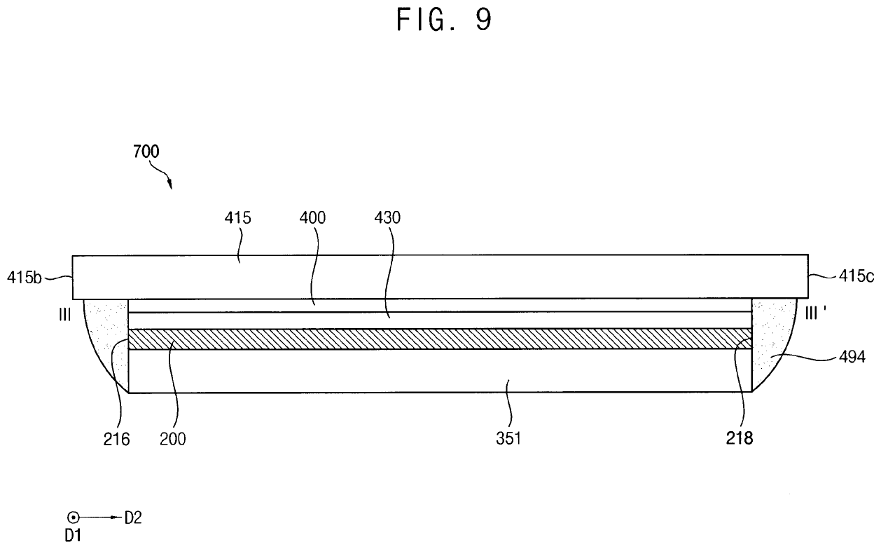

FIG. 7 is a plan view of another exemplary embodiment of a display device constructed according to principles of the invention. FIG. 8 is a cross-sectional view taken along line II-IF of FIG. 7. FIG. 9 is a cross-sectional view taken along line of FIG. 7.

The display device 700 illustrated in FIGS. 7, 8, and 9 may have a configuration substantially identical or similar to the configuration of the display device 100 described with reference to FIGS. 1 to 5 except for an adhesive member 494. In FIGS. 7, 8, and 9, redundant descriptions of components substantially identical or similar to the components described with reference to FIGS. 1 to 5 will be omitted to avoid redundancy.

Referring to FIGS. 7, 8, and 9, the display device 700 may include a display panel 200, a polarizing structure 430, a sensing structure 400, a lower protective film 300, an adhesive member 494, a cover window 415, and the like. In this case, the lower protective film 300 may include a first film 351 and a second film 352.

As shown in FIG. 8, the adhesive member 494 may be disposed between the bendable region 50 of the display panel 200 and the fourth protrusion 415d of the cover window 415, and may be disposed between the first protrusion 415a and a first side surface 212 of the display panel 200, and side surfaces of the sensing structure 400, the polarizing structure 430, and the first film 351. In addition, as shown in FIG. 9, the adhesive member 494 may be disposed between the second protrusion 415b and second side surfaces 216 of the display panel 200, the sensing structure 400, the polarizing structure 430, and the first film 351, and may be disposed between the third protrusion 415c and third side surfaces 218 of the display panel 200, the sensing structure 400, the polarizing structure 430, and the first film 351. In other words, the adhesive member 494 may simultaneously make direct contact with the top surface 204 of the display panel 200 located in the bendable region 50 and the bottom surface 418 of the fourth protrusion 415d of the cover window 415, and the adhesive member 494 may simultaneously make contact with bottom surfaces of the first to third protrusions 415a, 415b, and 415c and side surfaces 212, 216, and 218 of the display panel 200. In some embodiments, the adhesive member 494 may be additionally disposed in the space 450 defined by the bottom surface 208 of the display panel 200 located in the bendable region 50 and the side surfaces 360 and 362 of the first and second films 351 and 352 adjacent to the bendable region 50.

In the display device 700 according to the exemplary embodiments of the invention the adhesive member 494 simultaneously makes direct contact with the top surface 204 of the display panel 200 located in the bendable region 50 and the bottom surface 418 of the fourth protrusion 415d of the cover window 415 while simultaneously making contact with bottom surfaces of the first to third protrusions 415a, 415b, and 415c and the side surfaces of the display panel 200, so that the bendable region 50 of the display panel 200 (or the connection electrodes disposed in the bendable region 50) and the side surfaces of the display panel 200 may be protected from an external impact.

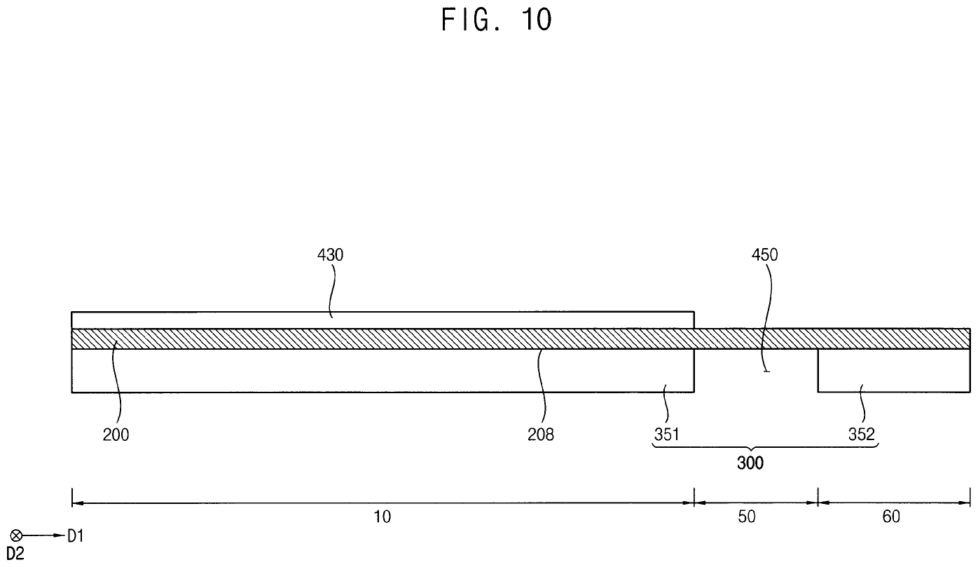

FIGS. 10, 11, 12, and 13 are cross-sectional views of an exemplary method of manufacturing a display device according to principles of the invention.

Referring to FIGS. 5 and 10, the display panel 200 including the substrate 110, the semiconductor element 250, the planarization layer 270, the lower electrode 290, the pixel defining layer 310, the light emitting layer 330, the upper electrode 340, the first thin film encapsulation layer 451, the second thin film encapsulation layer 452, the third thin film encapsulation layer 453, and the like may be provided. The display panel 200 may have the display region 10, the bendable region 50, and the pad region 60. The pad region 60 may be spaced apart from the display region 10, and the bendable region 50 may be located between the display region 10 and the pad region 60. For example, the pixels may be formed in the display region 10, and the image may be displayed through the pixels. The pad electrodes electrically connected to the external device 101 of FIG. 3 may be formed in the pad region 60, and the connection electrodes formed to electrically connect the pad electrode to the pixels may be formed in the bendable region 50.

The lower protective film 300 may be formed on the bottom surface 208 of the display panel 200. The lower protective film 300 may include the first film 351 and the second film 352. For example, the first film 351 may be formed on the bottom surface 208 of the display panel 200 located in the display region 10, and the second film 352 may be formed on the bottom surface 208 of the display panel 200 located in the pad region 60 while being spaced apart from the first film 351 on the bottom surface 208 of the display panel 200. In other words, the lower protective film 300 may expose the bottom surface 208 of the display panel 200 located in the bendable region 50. The lower protective film 300 may be formed of at least one of PET, PEN, PP, PC, PS, PSul, PE, PPA, PES, PAR, PCO, MPPO, and the like, as described above.

The polarizing structure 430 may be formed in the display region 10 on the display panel 200. In the exemplary embodiments, the polarizing structure 430 may be formed only in the display region 10 without being formed in the bendable region 50. The polarizing structure 430 may block external light incident to the display panel 200 from the outside. For example, the polarizing structure 430 may include the linear polarizing film and the λ/4 phase retardation film. The λ/4 phase retardation film may convert the phase of light. The λ/4 phase retardation film may be formed by using a birefringent film including at least one of a polymer, an alignment film formed of a liquid crystal polymer, a film including an alignment layer formed of a liquid crystal polymer, and the like. The linear polarizing film may be formed on the λ/4 phase retardation film. The linear polarizing film may selectively transmit light. The linear polarizing film may be formed by using at least one of an iodine-based material, a dye-containing material, a polyene-based material, and the like.

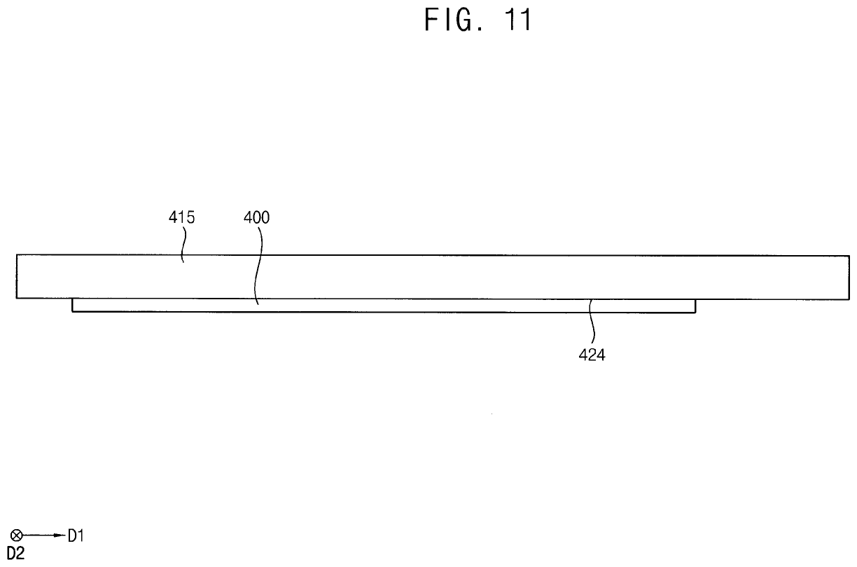

Referring to FIGS. 1 and 11, the cover window 415 may be provided. The cover window 415 may include at least one of tempered glass, tempered plastic, and the like.

The sensing structure 400 may be formed on a bottom surface 424 of the cover window 415. The sensing structure 400 may be substantially transparent. The sensing structure 400 may include sensing electrodes. In some embodiments, the sensing structure 400 may further include the connection wire formed to electrically connect the sensing electrode to the pad electrodes. The sensing electrodes and the connection wires may be formed by using at least one of CNT, TCO, ITO, IGZO, ZnO, graphene, AgNW, Cu, Cr, and the like. In other exemplary embodiments, an adhesive film may be interposed between the cover window 415 and the sensing structure 400. For example, the adhesive film may include at least one of an optical clear adhesive (OCA), a pressure sensitive adhesive (PSA), a UV resin, and the like.

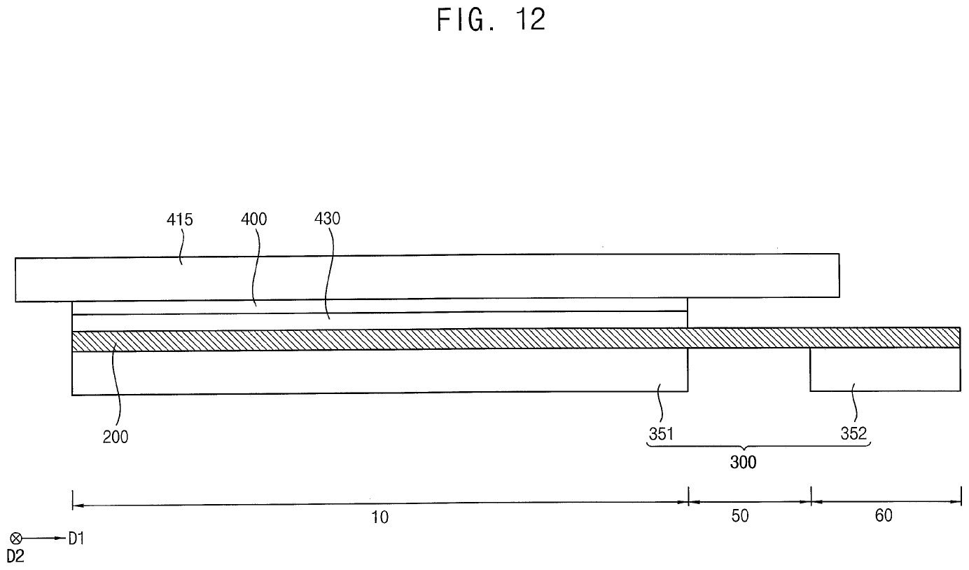

Referring to FIG. 12, the cover window 415 formed with the sensing structure 400 may be disposed on the polarizing structure 430. In other words, the sensing structure 400 may be located between the polarizing structure 430 and the cover window 415. In other exemplary embodiments, the adhesive film may be interposed between the polarizing structure 430 and the sensing structure 400.

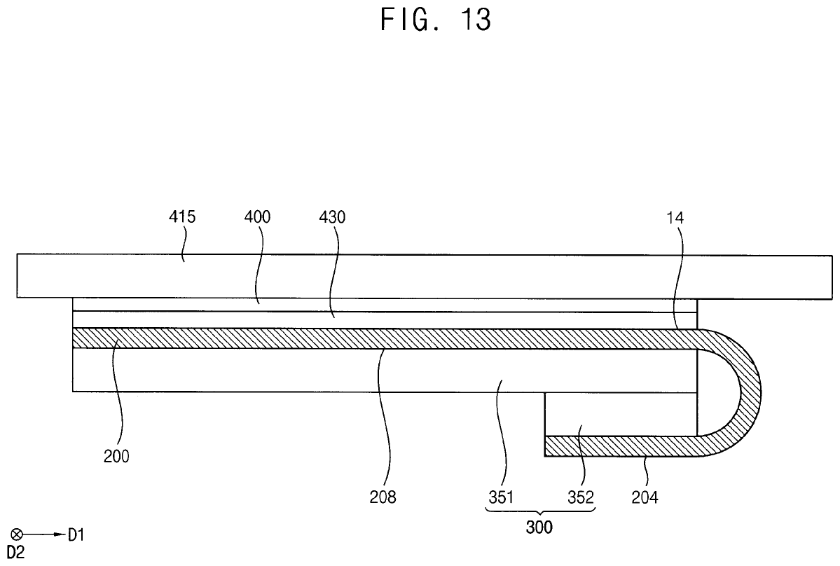

Referring to FIG. 13, the bendable region 50 of the display panel 200 may be bent. For example, when the bendable region 50 is bent, the pad region 60 may be located underneath the bottom surface 208 or on the inverted top surface 204 of the display panel 200, and a portion 14 of the display region 10 may overlap the pad region 60. In other words, when the display panel 200 is bent, the second film 352 may be located on the bottom surface of the first film 351. In other exemplary embodiments, a double-sided adhesive film may be interposed between the bottom surface of the first film 351 and the bottom surface of the second film 352.

Referring to FIGS. 1 and 4, the cover window 415 may further include the first, second, third, and fourth protrusions 415a, 415b, 415c, and 415d protruding from an outer periphery 402 of the display panel 200 located in the display region 10.

The adhesive member 490 may be formed between the bendable region 50 of the display panel 200 and the fourth protrusion 415d of the cover window 415. In the exemplary embodiments, the adhesive member 490 may simultaneously make direct contact with a top surface 204 of the display panel 200 located in the bendable region 50 and a bottom surface 418 of the fourth protrusion 415d of the cover window 415. In addition, the adhesive member 490 may make direct contact with a side surface 434 of the polarizing structure 430 and a side surface 404 of the sensing structure 400 which are adjacent to the bendable region 50 (or adjacent to the fourth protrusion 415d). Furthermore, the adhesive member 490 may extend from the bendable region 50 to the pad region 60 on the display panel 200. The adhesive member 490 may include at least one of an adhesive, a photocurable resin, a thermosetting resin, and the like. For example, the adhesive member 490 may be formed by using at least one of an epoxy resin, an amino resin, a phenol resin, a urea resin, a melamine resin, an unsaturated polyester resin, a polyurethane resin, a polyimide resin, and the like.

Accordingly, the display device 100 shown in FIGS. 1 to 5 may be manufactured according to the exemplary methods of the invention, and the adhesive member 490 is formed in the bendable region 50 of the display panel 200 after bending the bendable region 50 of the display panel 200. As an example, the cutting process of removing the bending protection layer may be omitted as in the conventional method of manufacturing the display device, and thus the manufacturing cost of the display device 100 may be relatively reduced. In other exemplary embodiments, as shown in FIG. 6, the adhesive member 490 may be additionally formed in the space 450 defined by the bottom surface 208 of the display panel 200 located in the bendable region 50 and the side surfaces 360 and 362 of the first and second films 351 and 352 adjacent to the bendable region 50.

The exemplary embodiments may be applied to various electronic devices including the display device. For example, the illustrated embodiments may be applied to one or more of a vehicle-display device, a ship-display device, an aircraft-display device, a portable communication device, a display device for display or for information transfer, a medical-display device, etc.

Although certain exemplary embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a display panel having a display region, a pad region, and a bendable region between the display region and the pad region;
a protective member on the display region and the bendable region of the display panel; and
an adhesive disposed in the bendable region in contact with a top surface of the display panel and a bottom surface of the protective member.

2. The display device of claim 1, wherein the pad region is at a bottom surface of the display panel when the bendable region is bent.

3. The display device of claim 2, wherein the display region comprises a portion overlapping the pad region.

4. The display device of claim 1, further comprising:
a polarizing structure disposed in the display region on the display panel; and
a sensing structure disposed between the polarizing structure and the protective member.

5. The display device of claim 4, wherein the adhesive comprises an adhesive member contacting a side surface of the polarizing structure and a side surface of the sensing structure, both of the side surfaces being adjacent to the bendable region.

6. The display device of claim 1, wherein the protective member comprises a cover window having a protrusion extending from an outer periphery of the display panel in the display region.

7. The display device of claim 6, wherein the adhesive contacts the side surfaces of the display panel and a bottom surface of the protrusion of the cover window.

8. The display device of claim 1, further comprising a lower protective film disposed on a bottom surface of the display panel.

9. The display device of claim 8, wherein the lower protective film exposes the bottom surface of the display panel located in the bendable region.

10. The display device of claim 8, wherein the lower protective film comprises:
a first film disposed on the bottom surface of the display panel in the display region; and
a second film disposed on the bottom surface of the display panel in the pad region and spaced apart from the first film on the bottom surface of the display panel.

11. The display device of claim 10, wherein the adhesive disposed in a space defined by the bottom surface of the display panel in the bendable region and side surfaces of the first and second films adjacent to the bendable region.

12. The display device of claim 1, wherein the adhesive comprises an adhesive member extending from the bendable region to the pad region on the display panel.

13. A method of manufacturing a display device, the method comprising the steps of:
providing a display panel having a display region, a pad region, and a bendable region located between the display region and the pad region;
forming a polarizing structure in the display region on the display panel;
providing a protective member;
forming a sensing structure on a bottom surface of the protective member;
forming the protective member with the sensing structure on the polarizing structure;
bending the bendable region of the display panel; and
forming an adhesive member in contact with a top surface of the display panel and the bottom surface of the protective member in the bendable region.

14. The method of claim 13, further comprising forming a lower protective film in the display region and the pad region on a bottom surface of the display panel.

15. The method of claim 14, wherein the lower protective film exposes the bottom surface of the display panel located in the bendable region.

16. The method of claim 14, wherein the step of forming the lower protective film in the display region and the pad region on the bottom surface of the display panel comprises:
forming a first film on the bottom surface of the display panel in the display region; and
forming a second film on the bottom surface of the display panel in the pad region spaced apart from the first film on the bottom surface of the display panel.

17. The method of claim 16, wherein the adhesive member is formed in a space defined by the bottom surface of the display panel in the bendable region and side surfaces of the first and second films adjacent to the bendable region.

18. The method of claim 13, wherein the pad region is disposed at a bottom surface of the display panel when the bendable region is bent, and
a portion of the display region overlaps the pad region.

19. The method of claim 13, wherein the adhesive member extends from the bendable region to the pad region on the display panel.

20. The method of claim 13, wherein the adhesive member contacts a side surface of the polarizing structure and a side surface of the sensing structure, both of the side surfaces being adjacent to the bendable region.
